(19) United States
(12) Patent Application Publication
(10) Pub. No.: US 2025/0036837 A1
(43) Pub. Date: Jan. 30, 2025

(54) MACHINE AND SYSTEMS FOR IDENTIFYING WELLS PRIORITY FOR CORROSION LOG UTILIZING MACHINE LEARNING MODEL

(71) Applicant: SAUDI ARABIAN OIL COMPANY, Dhahran (SA)

(72) Inventors: Ahmed Alqahtani, Al Hofuf (SA); Bayan Almomtan, Dammam (SA)

(73) Assignee: SAUDI ARABIAN OIL COMPANY, Dhahran (SA)

(21) Appl. No.: 18/361,676

(22) Filed: Jul. 28, 2023

(51) Int. Cl. G06F 30/28; G06F 30/27

(52) U.S. Cl. CPC G06F 30/28; G06F 30/27

(57) ABSTRACT

A method and a system for determining a well priority rank. The method includes obtaining well corrosion values and well barrier parameters, the well barrier parameters including properties of cement and casing and determining a corrosion severity rank using a machine learning model and based on the obtained well corrosion values and the obtained well barrier parameters. Further, the method includes determining the well priority rank based on the determined corrosion severity rank and well criticality features, the well criticality features indicating an amount of damage caused by a deterioration of a well. The determined well priority rank is used to generate a wellbore drilling plan.

### BACKGROUND

Corrosion of a well represents a degradation of a well structure or components of the well due to internal or external factors affecting the well. For example, the well may be exposed to water, oil, and/or gas behind the tubular element (such as gas behind the casing) that may cause various chemical reactions with pipe components, impacting the casing and thus well integrity over time. Likewise, it may prove difficult to adjust production parameters to account for changes in tubular element conditions without accurate knowledge of casing conditions at various depth intervals and/or well sections. Additionally, the corrosion may occur due to external factors such as cement channeling or cement bonding issues.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments disclosed herein relate to a method including obtaining well corrosion values and well barrier parameters, the well barrier parameters including properties of cement and casing and determining a corrosion severity rank using a machine learning model and based on the obtained well corrosion values and the obtained well barrier parameters. Further, the method includes determining a well priority rank based on the determined corrosion severity rank and well criticality features, the well criticality features indicating an amount of damage caused by a deterioration of a well. The determined well priority rank is used to generate a wellbore drilling plan.

In general, in one aspect, embodiments disclosed herein relate to a non-transitory computer readable medium storing a set of instructions executable by a computer processor for predicting well corrosion. The set of instructions includes the functionality for obtaining well corrosion values and well barrier parameters, the well barrier parameters including properties of cement and casing and determining a corrosion severity rank using a machine learning model and based on the obtained well corrosion values and the obtained well barrier parameters. Further, a well priority rank is determined based on the determined corrosion severity rank and well criticality features, the well criticality features indicating an amount of damage caused by a deterioration of a well. The determined well priority rank is used to generate a wellbore drilling plan.

In general, in one aspect, embodiments disclosed herein relate to a system including a well logging system and a well corrosion simulator comprising a functionality for obtaining well corrosion values and well barrier parameters, the well barrier parameters including properties of cement and casing and determining a corrosion severity rank using a machine learning model and based on the obtained well corrosion values and the obtained well barrier parameters. Further, a well priority rank is determined based on the determined corrosion severity rank and well criticality features, the well criticality features indicating an amount of damage caused by a deterioration of a well. The determined well priority rank is used to generate a wellbore drilling plan.

Other aspects and advantages of the claimed subject matter will be apparent from the following description and the appended claims.

### BRIEF DESCRIPTION OF DRAWINGS

Specific embodiments disclosed herein will now be described in detail with reference to the accompanying figures. Like elements in the various figures are denoted by like reference numerals for consistency. Like elements may not be labeled in all figures for the sake of simplicity.

FIG. 1 shows a system in accordance with one or more embodiments.

FIG. 2 shows a flowchart in accordance with one or more embodiments.

FIG. 3 shows a workflow for determining a well priority rank in accordance with one or more embodiments.

FIG. 4 shows a computer system in accordance with one or more embodiments.

### DETAILED DESCRIPTION

In the following detailed description of embodiments disclosed herein, numerous specific details are set forth in order to provide a more thorough understanding disclosed herein. However, it will be apparent to one of ordinary skill in the art that the invention may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers does not imply or create a particular ordering of the elements or limit any element to being only a single element unless expressly disclosed, such as by the use of the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

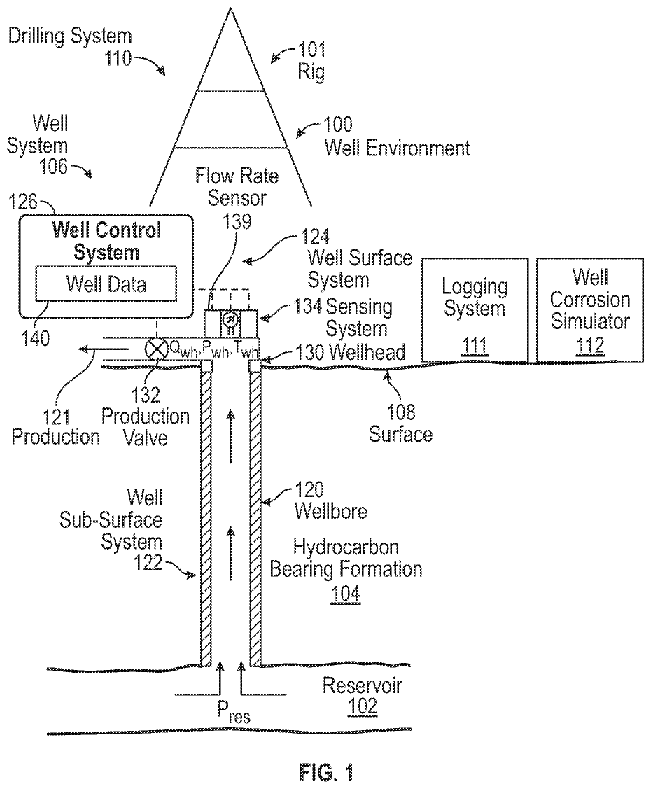

In the following description of FIGS. 1-4 any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a horizontal beam” includes reference to one or more of such beams.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Although multiple dependent claims are not introduced, it would be apparent to one of ordinary skill that the subject matter of the dependent claims of one or more embodiments may be combined with other dependent claims.

Embodiments disclosed herein provide a method and system for determining a well priority rank and generating a wellbore drilling plan based on the well priority rank. Specifically, the method predicts a corrosion severity rank based on the historic well corrosion logs, predicted well corrosion logs, and well barrier parameters. The historic well corrosion logs, predicted well corrosion logs, and well barrier parameters are processed and used as an input to a machine learning model based on a pointwise learn to rank algorithm. The corrosion severity rank is combined with well criticality features to obtain a well priority rank.

FIG. 1 shows a schematic diagram in accordance with one or more embodiments. As shown in FIG. 1, a well environment (100) includes a hydrocarbon reservoir (“reservoir”) (102) located in a subsurface hydrocarbon-bearing\ formation (“formation”) (104) and a well system (106). The hydrocarbon-bearing formation (104) may include a porous or fractured rock formation that resides underground, beneath a geological surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

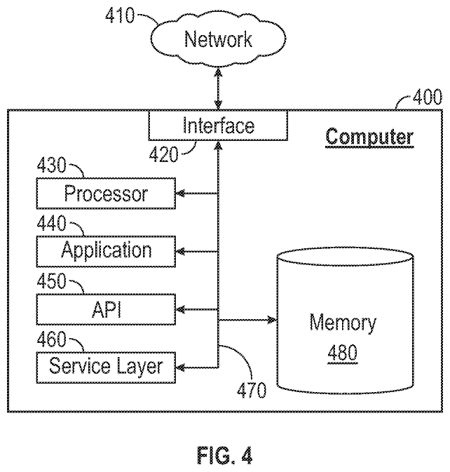

In some embodiments, the well system (106) includes a rig (101), a drilling system (110), a logging system (111), a well corrosion simulator (112), a wellbore (120), a well sub-surface system (122), a well surface system (124), and a well control system (“control system”) (126). The drilling system (110) may include a drill string, a drill bit, and a mud circulation system for use in drilling the wellbore (120) into the formation (104). The logging system (111) may include one or more logging tools, for use in generating well logs, based on the sensing system (134), of the formation (104). The well control system (126) may control various operations of the well system (106), such as well production operations, well drilling operation, well completion operations, well maintenance operations, and reservoir monitoring, assessment and development operations. In some embodiments, the well control system (126) includes a computer system that is the same as or similar to that of a computer system (400) described below in FIG. 4 and the accompanying description.

The rig (101) is a combination of equipment used to drill a borehole to form the wellbore (120). Major components of the rig (101) include the drilling fluid tanks, the drilling fluid pumps (e.g., rig mixing pumps), the derrick or mast, the draw works, the rotary table or top drive, the drill string, the power generation equipment and auxiliary equipment.

The wellbore (120) includes a bored hole (i.e., borehole) that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “downhole” end of the wellbore (120). The wellbore (120) may facilitate the circulation of drilling fluids during drilling operations, flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) lowered into the hydrocarbon-bearing formation (104) or the reservoir (102) during monitoring operations (e.g., during in situ logging operations).

In some embodiments, during operation of the well system (106), the well control system (126) collects and records well data (140) for the well system (106). During drilling operation of the well (106), the well data (140) may include mud properties, flow rates measured by a flow rate sensor (139), drill volume and penetration rates, formation characteristics, etc. To drill a subterranean well or wellbore (120), a drill string (110), including a drill bit and drill collars to weight the drill bit, may be inserted into a pre-drilled hole and rotated to cut into the rock at the bottom of the hole, producing rock cuttings. Commonly, the drilling fluid, or drilling mud, may be utilized during the drilling process. To remove the rock cuttings from the bottom of the wellbore (120), drilling fluid is pumped down through the drill string (110) to the drill bit. The drilling fluid may cool and lubricate the drill bit and provide hydrostatic pressure in the wellbore (120) to provide support to the sidewalls of the wellbore (120). The drilling fluid may also prevent the sidewalls from collapsing and caving in on the drill string (110) and prevent fluids in the downhole formations from flowing into the wellbore (120) during drilling operations. Additionally, the drilling fluid may lift the rock cuttings away from the drill bit and upwards as the drilling fluid is recirculated back to the surface. The drilling fluid may transport rock cuttings from the drill bit to the surface, which can be referred to as “cleaning” the wellbore (120), or hole cleaning.

In some embodiments, the well data (140) are recorded in real-time, and are available for review or use within seconds, minutes or hours of the condition being sensed (e.g., the measurements are available within 1 hour of the condition being sensed). In such an embodiment, the well data (140) may be referred to as “real-time” well data (140). Real-time well data (140) may enable an operator of the well (106) to assess a relatively current state of the well system (106), and make real-time decisions regarding a development of the well system (106) and the reservoir (102), such as on-demand adjustments in drilling fluid and regulation of production flow from the well.

In some embodiments, the well surface system (124) includes a wellhead (130). The wellhead (130) may include a rigid structure installed at the “up-hole” end of the wellbore (120), at or near where the wellbore (120) terminates at the geological surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (121). For example, a production valve (132) may be fully opened to enable the unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

In some embodiments, the wellhead (130) includes a choke assembly. For example, the choke assembly may include hardware with functionality for opening and closing the fluid flow through pipes in the well system (106). Likewise, the choke assembly may include a pipe manifold that may lower the pressure of fluid traversing the wellhead. As such, the choke assembly may include a set of high-pressure valves and at least two chokes. These chokes may be fixed or adjustable or a mix of both. Redundancy may be provided so that if one choke has to be taken out of service, the flow can be directed through another choke. In some embodiments, pressure valves and chokes are communicatively coupled to the well control system (126). Accordingly, a well control system (126) may obtain wellhead data regarding the choke assembly as well as transmit one or more commands to components within the choke assembly in order to adjust one or more choke assembly parameters.

Keeping with FIG. 1, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120). The surface sensing system (134) may also include sensors for sensing characteristics of the rig (101), such as bit depth, hole depth, drilling fluid flow, hook load, rotary speed, etc.

In some embodiments, the well system (106) includes the well corrosion simulator (112). For example, the well corrosion simulator (112) may include hardware and/or software with functionality for generating one or more reservoir models regarding the hydrocarbon-bearing formation (104) and/or performing one or more reservoir simulations. For example, the well corrosion simulator (112) may store the historic well corrosion logs, predicted well corrosion logs, and well barrier parameters. For this purpose, the simulator may include memory with one or more data structures, such as a buffer, a table, an array, or any other suitable storage medium. The well corrosion simulator (112) may further, at least, analyze the historic well corrosion logs, the predicted well corrosion logs, and the well barrier parameters, determine a corrosion severity rank, and determine a well priority rank. While well corrosion simulator (112) is shown at a well site, in some embodiments, the well corrosion simulator (112) may be located remotely from well site. In some embodiments, well corrosion simulator (112) may include a computer system that is similar to the computer system (400) described below with regard to FIG. 4 and the accompanying description.

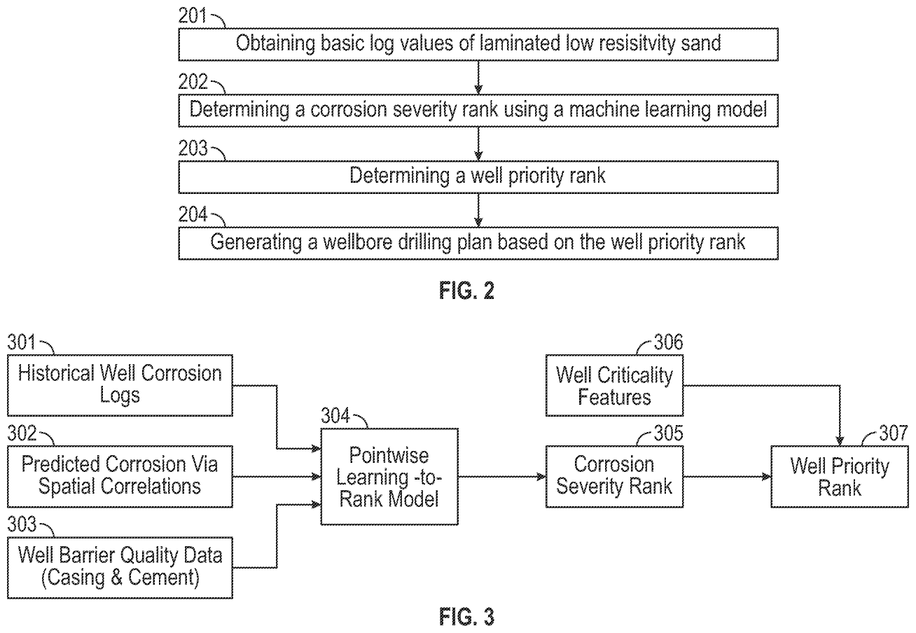

FIG. 2 shows a flowchart in accordance with one or more embodiments for determining well priority for corrosion log using machine learning models. Specifically, in Block 201, data is obtained/gathered from a plurality of sources. As shown on FIG. 3, historic well corrosion logs (301), predicted well corrosion logs (302), and well barrier parameters logs (303) are obtained. In one or more embodiments, historic well data may include predicted corrosion data from spatial correlation models and well barrier quality data. In one or more embodiments the historic well corrosion logs (301), the predicted corrosion logs (302), and the well barrier parameters logs (303) may be obtained in real-time. In other embodiments, the well corrosion logs (301), the predicted corrosion logs (302), and the well barrier parameters logs (303) may be obtained sequentially or immediately after drilling operations are performed.

The historic well corrosion logs (301) are obtained over a period of time and represent recorded data that measures presence of corrosion in the well. The well corrosion logs (301) may be obtained using specialized tools such as, as least, caliper tool, casing inspection tools, ultrasonic thickness gauge, electromagnetic corrosion logging tool, and acoustic logging tool. As obtaining the historic well corrosion logs (301) may be an expensive process that needs to be implemented for a long period of time, well corrosion logs may be generated using spatial correlation.

In one or more embodiments, the predicted well corrosion logs (302) may be generated using Kriging technique that generates corrosion log values at unmeasured location within a spatial domain based on the measured values at similar locations. Specifically, a field may be divided as a depth-wise layers. For each depth layer, a spatial model, such as a heatmap, may be generated to show the distribution of corrosion measurements around the field. Specifically, the technique uses spatial correlation between measured data points, that have a tendency to produce similar values. The spatial correlation may be determined using variogram function that measures a degree of spatial dependence between data points based on their separation distance, providing a linear prediction variance for any location on the map. This process may be repeated for each depth layer to generated predicted corrosion measurement for a plurality of depth layers.

Further, the well barrier parameters logs (303) may include information related to integrity of the barrier of the well including, at least, cement channeling and cement bonding. Issues with the cement channeling and the cement bonding may be caused as a result of contact between external factors and casing pipelines ultimately causing external corrosion. In one or more embodiments, cement bond logs may be obtained using a logging tool with, at least, acoustic or ultrasonic transducers, that is lowered into a wellbore. The logging tool initially transmits pulses in all directions and receives reflections of the emitted pulses. The received pulses may be processed to evaluate the integrity of the barrier of the well.

In one or more embodiments, the historic well corrosion logs (301), the predicted corrosion logs (302), and the well barrier parameters logs (303) may be preprocessed before being using to train, validate, and test a machine-learned model. Specifically, the data is gathered in Block 201 to train the LTR models (304). Preprocessing, at a minimum, comprises altering the data set so that it is suitable for use with machine-learned models. For example, numericalizing categorical data or removing data entries with missing values. Other typical preprocessing methods are normalization and imputation. In these cases, information surrounding the preprocessing steps is saved for potential later use. For example, if normalization is performed then a computed mean vector and variance vector are retained. This allows future input data to be preprocessed identically. Values computed and retained during preprocessing are referred to herein as preprocessing parameters. One with ordinary skill in the art will recognize that a myriad of preprocessing methods beyond numericalization, removal of data entries with missing values, normalization, and imputation exist. Descriptions of a select few preprocessing methods herein do not impose a limitation on the preprocessing steps encompassed by this disclosure.

In Block 202, and as shown in FIG. 3, embodiments the historic well corrosion logs (301), the predicted corrosion logs (302), and the well barrier parameters logs (303) are inputted to a trained machine learning (ML) model (304) to obtain a corrosion severity rank (305). The historic well corrosion logs (301), the predicted corrosion logs (302), and the well barrier parameters logs (303) are split into training, validation, and test sets. In some embodiments, the validation and test set may be the same such that the data is effectively only split into two distinct sets. For training and validation datasets, the wells that have historical corrosion logs showing the actual corrosion measured in the well may be used. Further, the last measured corrosion log is used to score wells based on actual measured corrosion severity in last well log.

In some instances, training the machine learning model (304) may be performed before preprocessing. In this case, it is common to determine the preprocessing parameters, if any, using the training set and then to apply these parameters to the validation and test sets. Additionally, the model may be regularly retrained, the model may be retrained when new surveys are collected, or when the accuracy threshold is modified.

The well corrosion simulator (112) may include hardware and/or software with functionality for generating and/or updating one or more machine learning models to determine a corrosion severity rank (305). In one or more embodiments, the machine learning models (304) may utilize a pointwise learning to rank (LTR) regression algorithm to predict and rank wells based on corrosion severity. Pointwise LTR machine learning algorithms is a class of techniques that apply supervised machine learning (ML) to solve ranking problems. Pointwise LTR approaches look at a single document at a time in the loss function. These types of ML ranking models essentially take a single document and train a regressor on it to predict how relevant it is for the current query. The final ranking is achieved by simply sorting the result list by these document scores. For pointwise approaches, the score for each document is independent of the other documents that are in the result list for the query.

Pointwise LTR models (304) may employ a plurality of machine learning algorithms including random forest models and artificial neural networks, such as convolutional neural networks, fully-connected neural networks, deep neural networks, and recurrent neural networks. Additionally, the pointwise LTR models may employ support vector machines, decision trees, inductive learning models, deductive learning models, supervised learning models, unsupervised learning models, reinforcement learning models, and the like. In a deep neural network, for example, a layer of neurons may be trained on a predetermined list of features based on the previous network layer's output. Thus, as data progresses through the deep neural network, more complex features may be identified within the data by neurons in later layers. In some embodiments, two or more different types of machine-learning models are integrated into a single machine-learning architecture, e.g., a machine-learning model may include a random forest model and various neural networks. In some embodiments, a simulator may generate augmented data or synthetic data to produce a large amount of interpreted data for training a particular model.

In some embodiments, various types of machine-learning algorithms may be used to train the model, such as a backpropagation algorithm. In a backpropagation algorithm, gradients are computed for each hidden layer of a neural network in reverse from the layer closest to the output layer proceeding to the layer closest to the input layer. As such, a gradient may be calculated using the transpose of the weights of a respective hidden layer based on an error function (also called a “loss function”). The error function may be based on various criteria, such as mean-squared-error (MSE) function, a similarity function, etc., where the error function may be used as a feedback mechanism for tuning weights in the machine-learning model.

In some embodiments, a machine learning model is trained using multiple epochs. For example, an epoch may be an iteration of a model through a portion or all of a training dataset. As such, a single machine-learning epoch may correspond to a specific batch of training data, where the training data is divided into multiple batches for multiple epochs. Thus, a machine-learning model may be trained iteratively using epochs until the model achieves a predetermined criterion, such as predetermined level of prediction accuracy or training over a specific number of machine-learning epochs or iterations. Thus, better training of a model may lead to better predictions by a trained model.

With respect to artificial neural networks, for example, an artificial neural network may include one or more hidden layers, where a hidden layer includes one or more neurons. A neuron may be a modelling node or object that is loosely patterned on a neuron of the human brain. In particular, a neuron may combine data inputs with a set of coefficients, i.e., a set of network weights for adjusting the data inputs. These network weights may amplify or reduce the value of a particular data input, thereby assigning an amount of significance to various data inputs for a task being modeled. Through machine learning, a neural network may determine which data inputs should receive greater priority in determining one or more specified outputs of the artificial neural network. Likewise, these weighted data inputs may be summed such that this sum is communicated through a neuron's activation function to other hidden layers within the artificial neural network. As such, the activation function may determine whether and to what extent an output of a neuron progresses to other neurons where the output may be weighted again for use as an input to the next hidden layer.

Turning to fully-connected neural networks, a fully connected neural network may include a series of fully connected layers (e.g., an input layer, one or more hidden layers, and an output layer) that connect each neuron in one layer to every neuron in the next layer. As such, fully-connected neural networks may be referred to as “structurally agnostic” in that there are no special assumptions needed to be made about the input data, such whether the input is an image, a continuous range of values, and/or categorized inputs.

Turning to convolution neural networks, a convolution neural network may obtain images as input data, which may allow encoding certain properties into the network's model architecture. For example, a convolution neural network may include a sequence of hidden layers, where a hidden layer may transform one volume of activations to another set of activations through a differentiable function. Examples of specific hidden layers in a convolution neural network include convolutional layers, pooling layers, fully-connected layers, and/or normalization layers. Likewise, a U-net model or other type of convolutional neural network model may use these different types of layers to produce a particular type of output.

Turning to recurrent neural networks, a recurrent neural network (RNN) may perform a particular task repeatedly for multiple data elements in an input sequence (e.g., a sequence of temperature values or flow rate values), with the output of the recurrent neural network being dependent on past computations. As such, a recurrent neural network may operate with a memory or hidden cell state, which provides information for use by the current cell computation with respect to the current data input. For example, a recurrent neural network may resemble a chain-like structure of RNN cells, where different types of recurrent neural networks may have different types of repeating RNN cells. Likewise, the input sequence may be time-series data, where hidden cell states may have different values at different time steps during a prediction or training operation. For example, where a deep neural network may use different parameters at each hidden layer, a recurrent neural network may have common parameters in an RNN cell, which may be performed across multiple time steps. To train a recurrent neural network, a supervised learning algorithm such as a backpropagation algorithm may also be used. In some embodiments, the backpropagation algorithm is a backpropagation through time (BPTT) algorithm. Likewise, a BPTT algorithm may determine gradients to update various hidden layers and neurons within a recurrent neural network in a similar manner as used to train various deep neural networks.

Embodiments are contemplated with different types of RNNs. For example, classic RNNs, long short-term memory (LSTM) networks, a gated recurrent unit (GRU), a stacked LSTM that includes multiple hidden LSTM layers (i.e., each LSTM layer includes multiple RNN cells), recurrent neural networks with attention (i.e., the machine-learning model may focus attention on specific elements in an input sequence), bidirectional recurrent neural networks (e.g., a machine-learning model that may be trained in both time directions simultaneously, with separate hidden layers, such as forward layers and backward layers), as well as multidimensional LSTM networks, graph recurrent neural networks, grid recurrent neural networks, etc. With regard to LSTM networks, an LSTM cell may include various output lines that carry vectors of information, e.g., from the output of one LSTM cell to the input of another LSTM cell. Thus, an LSTM cell may include multiple hidden layers as well as various pointwise operation units that perform computations such as vector addition.

In some embodiments, a simulator uses one or more ensemble learning methods to produce a hybrid-model architecture. For example, an ensemble learning method may use multiple types of machine-learning models to obtain better predictive performance than available with a single machine-learning model. In some embodiments, for example, an ensemble architecture may combine multiple base models to produce a single machine-learning model. One example of an ensemble learning method is a BAGGing model (i.e., BAGGing refers to a model that performs Bootstrapping and Aggregation operations) that combines predictions from multiple neural networks to add a bias that reduces variance of a single trained neural network model. Another ensemble learning method includes a stacking method, which may involve fitting many different model types on the same data and using another machine-learning model to combine various predictions.

Turning to random forests, a random forest model may an algorithmic model that combines the output of multiple decision trees to reach a single predicted result. For example, a random forest model may be composed of a collection of decision trees, where training the random forest model may be based on three main hyperparameters that include node size, a number of decision trees, and a number of input features being sampled. During training, a random forest model may allow different decision trees to randomly sample from a dataset with replacement (e.g., from a bootstrap sample) to produce multiple final decision trees in the trained model. For example, when multiple decision trees form an ensemble in the random forest model, this ensemble may determine more accurate predicted data, particularly when the individual trees are uncorrelated with each other. In some embodiments, a random forest model implements a software algorithm that is an extension of a bagging method. As, a random forest model may use both bagging and feature randomness to create an uncorrelated forest of decision trees. Feature randomness (also referred to as “feature bagging”) may generate a random subset of input features. This random subject may thereby result in low correlation among decision trees in the random forest model. In a training operation for a random forest model, a training operation may search for decision trees that provide the best split to subset particular data, such as through a Classification and Regression Tree (CART) algorithm. Different metrics, such as information gain or mean square error (MSE), may be used to determine the quality of a data split for various decision trees.

Keeping with random forests, a random forest model may be a classifier that uses data having discrete labels or classes. Likewise, a random forest model may also be used as a random forest regressor to solve regression problems. Depending on the type of problem being addressed by the random forest model, how predicted data is determined may vary accordingly. For a regression task, the individual decision trees may be averaged in a predicted result. For a classification task, a majority vote (e.g., predicting an output based on the most frequent categorical variable) may determine a predicted class. In a random forest regressor, the model may work with data having a numeric or continuous output, which cannot be defined by distinct classes.

Turning to reinforcement learning, a simulator may perform one or more reinforcement learning algorithms using a reinforcement learning system to train a machine-learning model. In particular, a reinforcement learning algorithm may be a type of method that autonomously learns agent policies through multiple iterations of trials and evaluations based on observation data. The objective of a reinforcement learning algorithm may be to learn an agent policy π that maps one or more states of an environment to an action so as to maximize an expected reward J(π). A value reward may describe one or more qualities of a particular state, agent action, and/or trajectory at particular time within an operation, such as an electric power generation operation. As such, a reinforcement learning system may include hardware and/or software with functionality for implementing one or more reinforcement learning algorithms. For example, a reinforcement learning algorithm may train a policy to make a sequence of decisions based on the observed states of the environment to maximize the cumulative reward determined by a reward function. For example, a reinforcement learning algorithm may employ a trial-and-error procedure to determine one or more agent policies based on various agent interactions with a complex environment, such as a geological subsurface with various geological interfaces and different formations. As such, a reinforcement learning algorithm may include a reward function that teaches a particular action selection engine to follow certain rules, while still allowing the reinforcement learning model to retain information learned from previous simulations.

In some embodiments, one or more components in a reinforcement learning system are trained using a training system. For example, an agent policy and/or a reward function may be updated through a training process that is performed by a machine-learning algorithm. In some embodiments, historical data, augmented data, and/or synthetic data may provide a supervised signal for training an action selector engine, an agent policy, and/or a reward function, such as through an imitation learning algorithm. In another embodiment, an interactive expert may provide data for adjusting agent policies and/or reward functions.

Turning to deep reinforcement learning, deep reinforcement learning may combine various machine-learning models (e.g., artificial neural networks) with a framework of reinforcement learning that helps agents learn how to reach their goals. That is, deep reinforcement learning may use both function approximation and target optimization in order to map various states and actions to specific rewards. For example, artificial neural networks as used in computer vision, natural language processing, and time series predictions may be combined with reinforcement learning algorithms.

In one or more embodiments, the output of the machine learning model is the corrosion severity rank, which includes a one score value per well indicating risk of deterioration of the well due to external corrosion. This score may be a discrete value on a scale from 0 to 3 quantifying the corrosion severity. For example, a corrosion severity rank of 0 may be assigned to a measured corrosion between 0-3%, the corrosion severity rank of 1 may be assigned to a measured corrosion between 3-10%, the corrosion severity rank of 2 may be assigned to a measured corrosion between 10-20%, and the corrosion severity rank of 3 may be assigned to a measured corrosion above >20%. In one or more embodiments, the corrosion severity rank calculated in Block 202 is not the final output, it is an intermediate output used to calculate the final output which is the well priority rank.

Thus, in Block 203 the corrosion severity rank, determined in Block 202, and well criticality features (306) are used to obtain a well priority rank (307). That is, priority of a well for logging depends on the risk of corrosion and well criticality. Specifically, the well criticality features (306) are represented as values that indicate the amount of damage to the people and environment in case of a potential leak caused by the corroded integrity of a well. In some embodiments, the wells may be classified into three groups (e.g., low, medium, and high) according to their well criticality features (306). The types of well criticality features may include a well type, a well rate and a well proximity to population or natural assets. Additionally, the user may classify the wells, according to their well criticality features (306) and based on predetermined rules for classification.

In one or more embodiments, the corrosion priority rank (307) may be calculated by combining the corrosion severity rank (305) and the well criticality features (306). Specifically, each group of the well criticality features (e.g., low, medium, and high) may be assigned with a predetermined multiplier (e.g., low=1, medium=1.2, and high=1.5). Further, the corrosion severity rank (305) may be multiplied with the predetermined multiplier assigned to a well criticality features' group. As such, high criticality wells will have their corrosion severity rank (305) increased the most, medium criticality wells will have their corrosion severity rank (305) increased by a multiplier smaller than the high criticality wells multiplier, and no adjustment will be made to low criticality wells.

Those skilled in the art will appreciate that in the case that all wells in the field have equal corrosion severity, wells priority rank will be mainly based on well criticality (impact on people and environment). Further, wells may be classified into predetermined groups based on their corrosion priority rank (307).

Further, in Block 204 the well priority rank (307) may be used directly to create a wellbore drilling plan using a wellbore planning system. Such a wellbore drilling plan may contain drilling targets including geological regions expected to contain hydrocarbons where drilling will not negatively affect the integrity of the nearby wells or the surrounding. The wellbore planning system may plan wellbore trajectories to reach the drilling targets while simultaneously avoiding drilling hazard, such as preexisting wellbores, shallow gas pockets, and fault zones, and not exceeding the constraints, such as torque, drag and wellbore curvature, of the drilling system. Similarly, the wellbore drilling plan may include a determination of wellbore caliper, and casing points.

The wellbore planning system may include dedicated software stored on a memory of a computer system, such as the computer system shown in FIG. 4. The wellbore plan may be informed by the best available information at the time of planning. This may include models encapsulating subterranean stress conditions, the trajectory of any existing wellbores (which may be desirable to avoid), and the existence of other drilling hazards, such as shallow gas pockets, over-pressure zones, and active fault planes.

The wellbore plan may further define associated drilling parameters, such as the planned depths at which casing will be inserted to support the wellbore to prevent formation fluids entering the wellbore and the drilling mud weights (densities) and types that may be used during drilling of the wellbore.

Additionally, well priority rank (307) may be used to rank a plurality of wells based on their integrity. Specifically, the wells with the highest well priority ranking (307) may be prioritized when generating one or more remediation processes, including well maintenance and reconstruction plans. Additionally, wells with the highest well priority ranking (307) may be operated in a different manner to ensure longer integrity of the well. Further if one or more wells have equal well priority ranking, the wells with higher well severity features may be prioritized to ensure the wellbeing of the humans and the environment.

Embodiments disclosed herein may be implemented on any suitable computing device, such as the computer system shown in FIG. 4. Specifically, FIG. 4 is a block diagram of a computer system (400) used to provide computational functionalities associated with described algorithms, methods, functions, processes, flows, and procedures as described in the instant disclosure, according to an implementation. The illustrated computer (400) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (400) may include a computer that includes an input device, such as a keypad, keyboard, touch screen, or other device that can accept user information, and an output device that conveys information associated with the operation of the computer (400), including digital data, visual, or audio information (or a combination of information), or a GUI.

The computer (400) can serve in a role as a client, network component, a server, a database or other persistency, or any other component (or a combination of roles) of a computer system for performing the subject matter described in the instant disclosure. The illustrated computer (400) is communicably coupled with a network (410). In some implementations, one or more components of the computer (400) may be configured to operate within environments, including cloud-computing-based, local, global, or other environment (or a combination of environments).

At a high level, the computer (400) is an electronic computing device operable to receive, transmit, process, store, or manage data and information associated with the described subject matter. According to some implementations, the computer (400) may also include or be communicably coupled with an application server, e-mail server, web server, caching server, streaming data server, business intelligence (BI) server, or other server (or a combination of servers).

The computer (400) can receive requests over network (410) from a client application (for example, executing on another computer (400) and responding to the received requests by processing the said requests in an appropriate software application. In addition, requests may also be sent to the computer (400) from internal users (for example, from a command console or by other appropriate access method), external or third-parties, other automated applications, as well as any other appropriate entities, individuals, systems, or computers.

Each of the components of the computer (400) can communicate using a system bus (470). In some implementations, any or all of the components of the computer (400), both hardware or software (or a combination of hardware and software), may interface with each other or the interface (420) (or a combination of both) over the system bus (470) using an application programming interface (API) (450) or a service layer (460) (or a combination of the API (450) and service layer (460). The API (450) may include specifications for routines, data structures, and object classes. The API (450) may be either computer-language independent or dependent and refer to a complete interface, a single function, or even a set of APIs. The service layer (460) provides software services to the computer (400) or other components (whether or not illustrated) that are communicably coupled to the computer (400). The functionality of the computer (400) may be accessible for all service consumers using this service layer. Software services, such as those provided by the service layer (460), provide reusable, defined business functionalities through a defined interface. For example, the interface may be software written in JAVA, C++, or other suitable language providing data in extensible markup language (XML) format or other suitable format. While illustrated as an integrated component of the computer (400), alternative implementations may illustrate the API (450) or the service layer (460) as stand-alone components in relation to other components of the computer (400) or other components (whether or not illustrated) that are communicably coupled to the computer (400). Moreover, any or all parts of the API (450) or the service layer (460) may be implemented as child or sub-modules of another software module, enterprise application, or hardware module without departing from the scope of this disclosure.

The computer (400) includes an interface (420). Although illustrated as a single interface (420) in FIG. 4, two or more interfaces (420) may be used according to particular needs, desires, or particular implementations of the computer (400). The interface (420) is used by the computer (400) for communicating with other systems in a distributed environment that are connected to the network (410). Generally, the interface (420 includes logic encoded in software or hardware (or a combination of software and hardware) and operable to communicate with the network (410). More specifically, the interface (420) may include software supporting one or more communication protocols associated with communications such that the network (410) or interface's hardware is operable to communicate physical signals within and outside of the illustrated computer (400).

The computer (400) includes at least one computer processor (430). Although illustrated as a single computer processor (430) in FIG. 4, two or more processors may be used according to particular needs, desires, or particular implementations of the computer (400). Generally, the computer processor (430) executes instructions and manipulates data to perform the operations of the computer (400) and any algorithms, methods, functions, processes, flows, and procedures as described in the instant disclosure.

The computer (400) also includes a memory (480) that holds data for the computer (400) or other components (or a combination of both) that can be connected to the network (410). For example, memory (480) can be a database storing data consistent with this disclosure. Although illustrated as a single memory (480) in FIG. 4, two or more memories may be used according to particular needs, desires, or particular implementations of the computer (400) and the described functionality. While memory (480) is illustrated as an integral component of the computer (400), in alternative implementations, memory (480) can be external to the computer (400).

The application (440) is an algorithmic software engine providing functionality according to particular needs, desires, or particular implementations of the computer (400), particularly with respect to functionality described in this disclosure. For example, application (440) can serve as one or more components, modules, applications, etc. Further, although illustrated as a single application (440), the application (440) may be implemented as multiple applications (440) on the computer (400). In addition, although illustrated as integral to the computer (400), in alternative implementations, the application (440) can be external to the computer (400).

There may be any number of computers (400) associated with, or external to, a computer system containing computer (400), each computer (400) communicating over network (410). Further, the term “client,” “user,” and other appropriate terminology may be used interchangeably as appropriate without departing from the scope of this disclosure. Moreover, this disclosure contemplates that many users may use one computer (400), or that one user may use multiple computers (400).

In some embodiments, the computer (400) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method for predicting well corrosion, comprising:
obtaining, using a computer processor, well corrosion values and well barrier parameters, the well barrier parameters including properties of cement and casing;
determining, using the computer processor, a corrosion severity rank using a machine learning model and based on the obtained well corrosion values and the obtained well barrier parameters;
determining, using the computer processor, a well priority rank based on the determined corrosion severity rank and well criticality features, the well criticality features indicating an amount of damage caused by a deterioration of a well; and
generating, using the computer processor, a wellbore drilling plan based on the determined well priority rank.

2. The method of claim 1, wherein a plurality of wells is ranked based on the well priority rank, and wherein an action plan is generated based on the ranking of the plurality of wells.

3. The method of claim 2, wherein the wells are classified into predetermined groups based on the well criticality features,
wherein, a multiplier is assigned to each predetermined group, and
wherein, the well priority rank is calculated by multiplying the corrosion severity rank and the multiplier.

4. The method of claim 1, wherein the well corrosion values may be historical well corrosion values that are obtained over time or predicted well corrosion values.

5. The method of claim 4, wherein the predicted well corrosion values are generated using Kriging technique that generates corrosion log values at unmeasured location within a spatial domain based on measured values at similar locations.

6. The method of claim 1, wherein the well corrosion values and the well barrier parameters are preprocessed before being inputted into the machine learning model.

7. The method of claim 1, wherein the machine learning model uses pointwise learn to rank algorithm.

8. A non-transitory computer readable medium storing instructions executable by a computer processor, the instructions comprising functionality for:
obtaining well corrosion values and well barrier parameters, the well barrier parameters including properties of cement and casing;
determining a corrosion severity rank using a machine learning model and based on the obtained well corrosion values and the obtained well barrier parameters;
determining a well priority rank based on the determined corrosion severity rank and well criticality features, the well criticality features indicating an amount of damage caused by a deterioration of a well; and
generating a wellbore drilling plan based on the determined well priority rank.

9. The non-transitory computer readable medium of claim 8, wherein a plurality of wells is ranked based on the well priority rank, and wherein an action plan is generated based on the ranking of the plurality of wells.

10. The non-transitory computer readable medium of claim 9, wherein the wells are classified into predetermined groups based on the well criticality features,
wherein, a multiplier is assigned to each predetermined group, and
wherein, the well priority rank is calculated by multiplying the corrosion severity rank and the multiplier.

11. The non-transitory computer readable medium of claim 8, wherein the well corrosion values may be historical well corrosion values that are obtained over time or predicted well corrosion values.

12. The non-transitory computer readable medium of claim 11, wherein the predicted well corrosion values are generated using Kriging technique that generates corrosion log values at unmeasured location within a spatial domain based on measured values at similar locations.

13. The non-transitory computer readable medium of claim 8, wherein the well corrosion values and the well barrier parameters are preprocessed before being inputted into the machine learning model.

14. A system comprising:
a well logging system; and
a well corrosion simulator comprising a computer processor, wherein the well corrosion simulator is coupled to the well logging, the well corrosion simulator comprising functionality for:
obtaining well corrosion values and well barrier parameters, the well barrier parameters including properties of cement and casing;
determining a corrosion severity rank using a machine learning model and based on the obtained well corrosion values and the obtained well barrier parameters;
determining a well priority rank based on the determined corrosion severity rank and well criticality features, the well criticality features indicating an amount of damage caused by a deterioration of a well; and
generating a wellbore drilling plan based on the determined well priority rank.

15. The system of claim 14, wherein a plurality of wells is ranked based on the well priority rank, and wherein an action plan is generated based on the ranking of the plurality of wells.

16. The system of claim 15, wherein the wells are classified into predetermined groups based on the well criticality features,
wherein, a multiplier is assigned to each predetermined group, and
wherein, the well priority rank is calculated by multiplying the corrosion severity rank and the multiplier.

17. The system of claim 14, wherein the well corrosion values may be historical well corrosion values that are obtained over time or predicted well corrosion values.

18. The system of claim 17, wherein the predicted well corrosion values are generated using Kriging technique that generates corrosion log values at unmeasured location within a spatial domain based on measured values at similar locations.

19. The system of claim 14, wherein the well corrosion values and the well barrier parameters are preprocessed before being inputted into the machine learning model.

20. The system of claim 14, wherein the machine learning model uses pointwise learn to rank algorithm.
